(19) United States
(12) Patent Application Publication
(10) Pub. No.: US 2024/0304536 A1
(43) Pub. Date: Sep. 12, 2024

(54) HIGH DENSITY PACKAGING ELECTROMIGRATION PROTECTION LAYER

(71) Applicant: Intel Corporation, Santa Calra, CA (US)

(72) Inventors: Sanjay THARMARAJAH, Queen Creek, AZ (US); Kristof DARMAWIKARTA, Chandler, AZ (US)

(21) Appl. No.: 18/120,172

(22) Filed: Mar. 10, 2023

(51) Int. Cl. H01L 23/498; H01L 23/532

(52) U.S. Cl. CPC H01L 23/49838; H01L 23/49822; H01L 23/49866; H01L 23/53238; H01L 24/13; H01L 24/16; H01L 2224/13147; H01L 2224/16227

(57) ABSTRACT

Embodiments disclosed herein include package substrates. In an embodiment, the package substrate comprises a substrate layer, and a plurality of traces on the substrate layer. In an embodiment, each of the plurality of traces are covered on sidewalls and an entire top surface by a first layer. In an embodiment, a pad is on the substrate layer, where the pad is covered on sidewalls and an entire top surface by a second layer.

### TECHNICAL FIELD

Embodiments of the present disclosure relate to electronic systems, and more particularly to package substrates that include high density electrical routing with electromigration protection layers.

### BACKGROUND

Fine pitch redistribution layer (RDL) technology is a novel approach to achieving high density packaging. As used herein, fine pitch may refer to line/space (L/S) dimensions that are approximately 5 μm/5 μm or less. However, such fine pitches may result in reliability issues. One major reliability issue is due to electromigration failure related mechanisms. This failure mode limits design rules to certain geometries and lengths of copper traces. Further, such issues impact the overall life cycle of a package due to electromigration failures.

Design rules that are currently in place for such architectures include trace length and trace geometry. Typically, bent lines (e.g., with a 45 degree bend or turn) exhibit better reliability performance compared to straight lines. Such design rule mitigation will impact the number of fan out traces and the length of such traces. This limits the number of redundancy fallbacks for reliability in high density patterning (HDP) products.

### BRIEF DESCRIPTION OF THE DRAWINGS

FIG. 1A is a plan view illustration of a package substrate with traces and pads, in accordance with an embodiment.

FIG. 1B is a plan view illustration of a package substrate with a void along one of the traces between pads, in accordance with an embodiment.

FIG. 2A is a cross-sectional illustration of a package substrate with high density line/spacing (L/S) traces and a pad, in accordance with an embodiment.

FIG. 2B is a cross-sectional illustration of the package substrate with a barrier layer provided over the traces, the pad, and the underlying package substrate, in accordance with an embodiment.

FIG. 2C is a cross-sectional illustration of the package substrate after another buildup layer is provided over the package substrate, in accordance with an embodiment.

FIG. 2D is a cross-sectional illustration of the package substrate after a via opening is formed through the second buildup layer, in accordance with an embodiment.

FIG. 2E is a cross-sectional illustration of the package substrate after the barrier layer is etched at the bottom of the via opening, in accordance with an embodiment.

FIG. 2F is a cross-sectional illustration after a via is formed in the via opening, in accordance with an embodiment.

FIG. 3A is a cross-sectional illustration of a package substrate with traces that have a small L/S dimension with a pad, in accordance with an embodiment.

FIG. 3B is a cross-sectional illustration of the package substrate with a barrier layer provided over sidewalls and top surfaces of the traces and the pads, in accordance with an embodiment.

FIG. 3C is a cross-sectional illustration of the package substrate after a second buildup layer is provided over the package substrate, in accordance with an embodiment.

FIG. 3D is a cross-sectional illustration of the package substrate after a via opening is formed in the second buildup layer, in accordance with an embodiment.

FIG. 3E is a cross-sectional illustration of the package substrate after a via is formed in the via opening, in accordance with an embodiment.

FIG. 4A is a plan view illustration of a package substrate with fine L/S traces with straight lines, in accordance with an embodiment.

FIG. 4B is a plan view illustration of a package substrate with fine L/S traces with bends or turns, in accordance with an embodiment.

FIG. 5 is a cross-sectional illustration of an electronic system with a package substrate that includes fine L/S traces with a conductive barrier layer, in accordance with an embodiment.

FIG. 6 is a schematic of a computing device built in accordance with an embodiment.

### EMBODIMENTS OF THE PRESENT DISCLOSURE

Described herein are electronic systems, and more particularly package substrates that include high density electrical routing with electromigration protection layers, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, fine line/space (L/S) dimensions allow for improved high density patterning (HDP) architectures. As such, more signaling traces can be provided within a footprint of a package substrate. As used herein, fine L/S dimensions may include dimension of approximately 5 μm/5 μm or lower. For example, in some instances, fine L/S dimensions may include dimensions of approximately 3 μm/3 μm. As used herein, “approximately” may refer to a range of values within ten percent of the stated value. For example, approximately 5 μm may refer to a range between 4.5 μm and 5.5 μm.

While fine L/S dimensions are preferable for forming more traces within a given area, reducing the L/S dimensions results in certain drawbacks. One such drawback is the presence or occurrence of electromigration issues. That is, at such small dimensions, the diffusion of the conductive material (e.g., copper) can result in the generation of voids or breaks along the conductive trace. This provides significant reliability issues in the package substrate and need to be avoided.

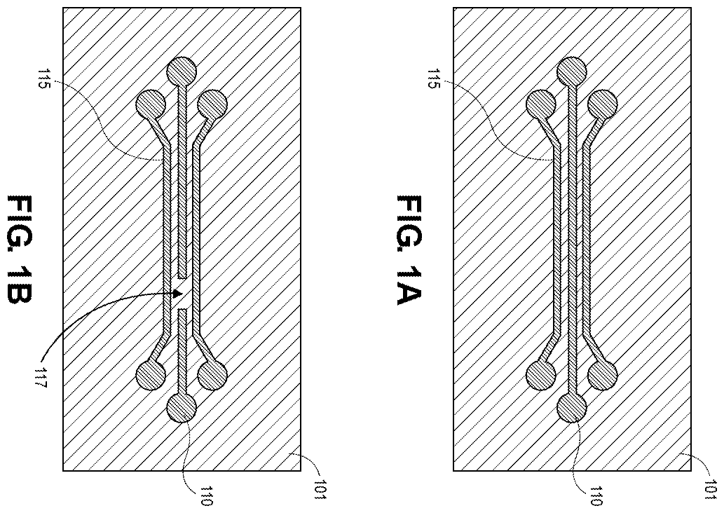

Referring now to FIG. 1A, a plan view illustration of a portion of an electronic package is shown, in accordance with an embodiment. The electronic package may include a package substrate 101. The package substrate 101 may be an organic buildup film or the like. The package substrate 101 may be provided over underlying buildup layers or over a core (e.g., a glass core, an organic core, etc.). In an embodiment, a plurality of pads 110 may be provided on the package substrate. Pairs of the pads 110 may be electrically coupled together by traces 115. In an embodiment, the traces 115 may have L/S dimensions that are approximately 5 μm/5 μm or lower. That is, the width of each of the traces 115 may be up to approximately 5 μm and the spacing between traces 115 may be up to approximately 5 μm. The traces 115 and the pads 110 may comprise copper or any other conductive material or materials. In an embodiment, the traces 115 may include straight line traces 115 and/or bent line traces 115. For example, a straight line trace 115 is provided between a pair of bent line traces 115 in FIG. 1A.

Referring now to FIG. 1B, a plan view illustration of a portion of the electronic package is shown after some duration of time. As illustrated, a void 117 may be generated along one or more of the traces 115. For example, the void 117 in FIG. 1B is shown along the middle straight trace 115. The void 117 may be the result of electromigration of the copper or other conductive materials. Particularly, due to the small dimension of the traces 115, small amounts of diffusion away from the trace 115 may result in the formation of the void 117. This can provide a significant reliability risk for the electronic package. As such, additional traces 115 may be needed in order to function as backups in the case electromigration damages one or more of the traces. The need to provide additional routing traces negates the benefits provided by the fine L/S dimensions.

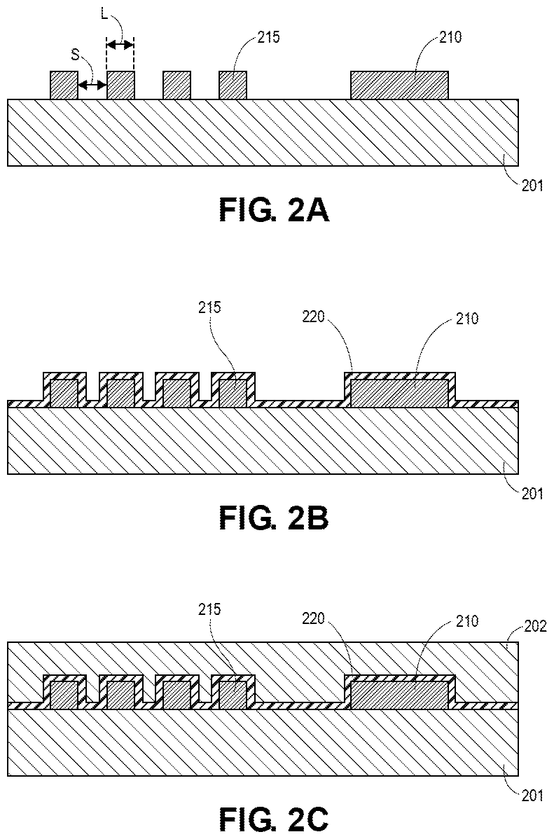

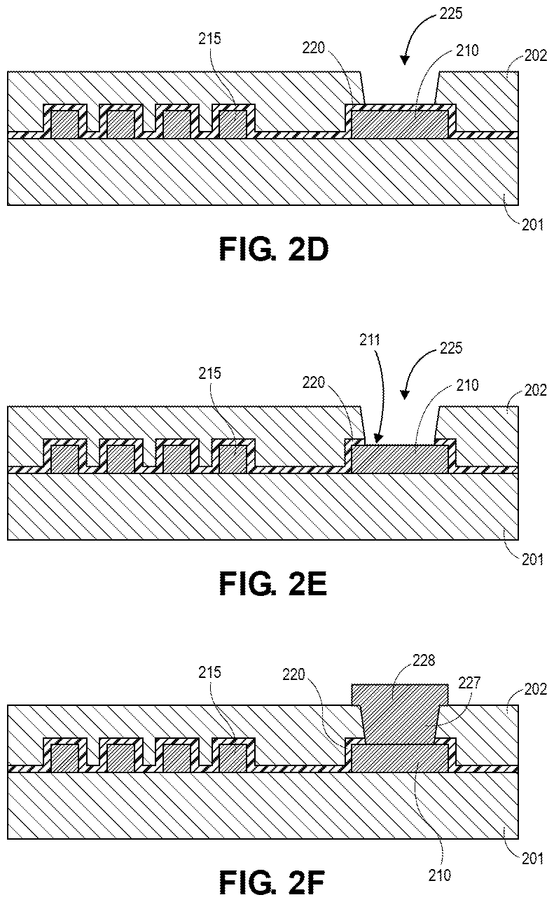

Various manufacturing operations can be used in order to mitigate the formation of voids 117 due to electromigration. One solution is to provide a diffusion barrier layer (also referred to simply as a barrier layer). The barrier layer may comprise a material composition that serves as a barrier to prevent out diffusion of copper from the traces. Improved performance is provided when the entire surface of the trace and/or pad is covered by the barrier layer. That is, the sidewalls and top surface of the trace and/or pad is covered by the barrier layer. An example of such a barrier layer is shown in FIGS. 2A-2F.

Referring now to FIG. 2A, a cross-sectional illustration of a portion of an electronic package is shown, in accordance with an embodiment. The electronic package may comprise a package substrate 201. The package substrate 201 may be a buildup layer, such as an organic buildup film. While shown in isolation, it is to be appreciated that the package substrate 201 may be provided on an underlying buildup layer, over a core, or the like.

In an embodiment, conductive routing may be provided over a surface of the package substrate 201. For example, conductive traces 215 may be provided over the package substrate 201. The conductive traces 215 may have a L/S dimension that is up to approximately 5 μm/5 μm. In the illustrated embodiment, the traces 215 are oriented so that they extend into and out of the plane of FIG. 2A. The traces 215 may comprise copper or any other conductive material or materials. In an embodiment, the conductive routing may further comprise one or more pads 210. The pad 210 in FIG. 2A may be electrically coupled to a trace 215. The pad 210 may have a diameter that is greater than a dimension of the traces 215. The pad 210 may comprise the same material or materials as the traces 215.

Referring now to FIG. 2B, a cross-sectional illustration of the electronic package after formation of a barrier layer 220 is shown, in accordance with an embodiment. In an embodiment, the barrier layer 220 may be an electrically insulating material. For example, the barrier layer 220 may comprise silicon and nitrogen (e.g., SiN_{X}). The barrier layer 220 may be applied with a blanket deposition process. For example, a chemical vapor deposition (CVD) process may be used in some embodiments. The thickness of the barrier layer 220 may be approximately 1 μm or greater in some embodiments. Due to the blanket deposition process, the barrier layer 220 may be applied over the surfaces of the pad 210, the traces 215, and over the top surface of the package substrate 201.

Referring now to FIG. 2C, a cross-sectional illustration of the electronic package after a second package substrate 202 is provided over the package substrate 201 is shown, in accordance with an embodiment. The second package substrate 202 may comprise the same material as the package substrate 201. The second package substrate 202 may be applied with a lamination process, or the like. As shown, the bottom surface of the package substrate 202 is provided in direct contact with the barrier layer 220.

Referring now to FIG. 2D, a cross-sectional illustration of the electronic package after a via opening 225 is formed through the package substrate 202 is shown, in accordance with an embodiment. The via opening 225 may be provided over the pad 210. The via opening 225 may be formed with a laser drilling process or the like. As shown, the via opening 225 exposes a portion of the barrier layer 220 over the pad 210. Since the barrier layer 220 is electrically insulating, the barrier layer 220 may also need to be removed in a subsequent processing operation.

Referring now to FIG. 2E, a cross-sectional illustration of the electronic package after the exposed portion of the barrier layer 220 is removed is shown, in accordance with an embodiment. In an embodiment, the barrier layer 220 may be removed with an etching process. In some embodiments, the etching process is a wet etching process. Since the via opening 225 and the barrier layer 220 are removed with different processes, the sidewalls of the via opening 225 (e.g., tapered sidewalls) may have a different profile than the sidewalls of the barrier layer 220 (e.g., vertical sidewalls). Removal of the barrier layer 220 results in the exposure of a top surface 211 of the pad 210. As such, a subsequently formed via in the via opening 225 may make electrical contact with the pad 210.

Referring now to FIG. 2F, a cross-sectional illustration of the electronic package after the formation of a via 227 and an overlying pad 228 is shown, in accordance with an embodiment. The via 227 and the overlying pad 228 may comprise an electrically conductive material, such as copper or the like. As shown, the via 227 lands directly on the pad 210. As such, an electrical connection between the overlying pad 228 and the pad 210 is provided.

While the example process flow shown in FIG. 2A-2F provided electrical coupling between layers, while protecting against electromigration failures, it is to be appreciated that additional processing operations are needed. For example, the barrier layer 220 needs to be etched subsequent to the formation of the via opening. Also, the barrier layer 220 is a blanket deposited layer. This results in the second package substrate 202 being separated from the package substrate 201. As such, the adhesion between layers may be negatively impacted.

Accordingly, embodiments disclosed herein include electromigration limiting barrier layers that are conductive materials. For example, the barrier layers disclosed herein may comprise cobalt or the like. In a particular embodiment, the barrier layer may comprise cobalt, tungsten, and a phosphate (e.g., CoWP). Since the barrier layer is electrically conducting, an additional etching process is not needed to remove the barrier layer during formation of overlying vias. The presence of such a barrier layer may lead to an approximately 300 times increase in the electromigration of copper traces. The improved electromigration characteristics allow for design rules to be relaxed to allow for alternative connections and trace dimensions that were previously high risk for electromigration failure. For example, straight traces and traces with longer lengths (e.g., up to 600 μm or longer) may be enabled using embodiments disclosed herein. Layers as thin as approximately 10 Angstroms may be used in some embodiments. Though, barrier layers with thicknesses up to approximately 1 nm may also be used in some embodiments. Further, the use of a conductive barrier layer allows for selective deposition of the barrier layer over only conductive features. For example, an autocatalytic reaction may be used to selectively deposit the barrier layer over only the exposed traces and pads. This allows for improved adhesion between package substrate layers.

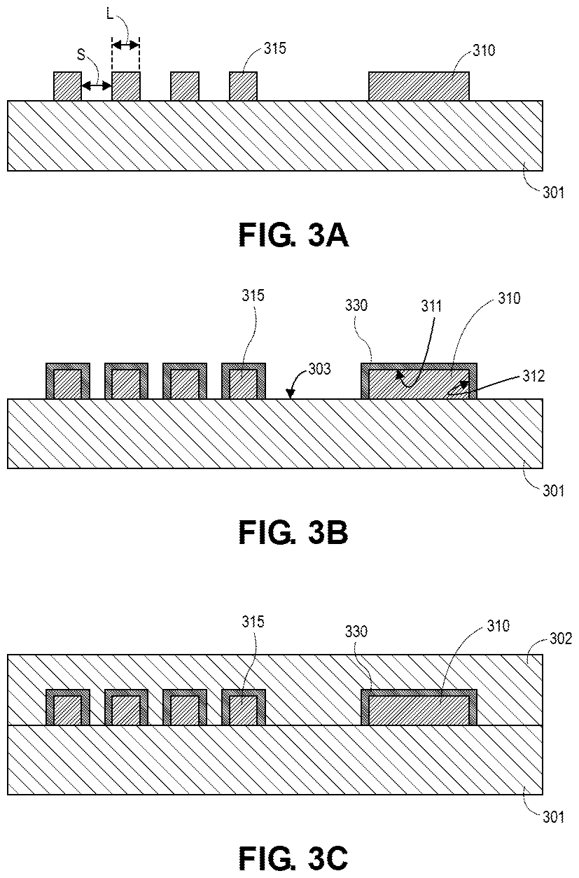

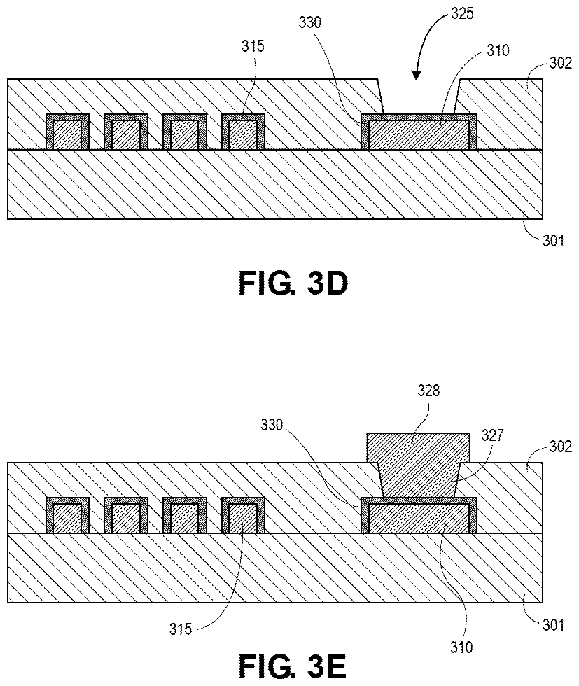

Referring now to FIGS. 3A-3E, a series of cross-sectional illustrations depicting a process for forming an electronic package with improved electromigration performance is shown, in accordance with an embodiment. In an embodiment, the electromigration performance is improved as a result of an electrically conductive barrier layer. While shown as being used for an electronic packaging application, it is to be appreciated that other structures may also benefit from similar barrier layers. For example, wafer level process may also utilize similar electrically conductive barrier layers in order to improve electromigration performance.

Referring now to FIG. 3A, a cross-sectional illustration of a portion of an electronic package is shown, in accordance with an embodiment. In an embodiment, the electronic package may comprise a first package substrate layer 301. The first package substrate layer 301 may be an organic buildup film or the like. In an embodiment, the first package substrate layer 301 may be provided over an underlying package substrate layer or a core. For example, the core may comprise a glass core or an organic core. Though, it is to be appreciated that the electronic package may be coreless in some embodiments. Further while described in the context of an electronic package, other embodiments may include a wafer level processing application. In such embodiments, the first package substrate layer 301 may be a back-end-of-line (BEOL) routing layer over an underlying semiconductor wafer that will ultimately be diced into individual dies.

In an embodiment, the electronic package may further comprise a plurality of traces 315. The traces 315 may comprise copper traces or other electrically conductive material or materials. The traces 315 may be high density routing traces 315. For example, L/S dimensions of the traces 315 may be approximately 5 μm/5 μm or less. For example, the L/S dimensions may be approximately 3 μm/3 μm in some embodiments. While line width dimensions L are shown as being substantially equal to space dimensions S, it is to be appreciated that the L dimension and the S dimension need not be substantially equal to each other in all embodiments.

In an embodiment, one or more pads 310 may also be provided over the first package substrate layer 301. The pads 310 may have a diameter that is up to approximately 20 μm in some embodiments. For example, the diameter of the pad 310 may be between approximately 5 μm and approximately 15 μm in some embodiments. The pads 310 may also comprise a conductive material, such as copper or other electrically conductive material or materials. The thickness of the pad 310 may be substantially similar to the thickness of the traces 315 in some embodiments.

Referring now to FIG. 3B, a cross-sectional illustration of the electronic package after the formation of a barrier layer 330 is shown, in accordance with an embodiment. The barrier layer 330 may comprise cobalt in some embodiments. Though, in other embodiments, the barrier layer 330 may comprise cobalt, tungsten, and a phosphate (e.g., CoWP). The barrier layer 330 may have a thickness that is up to approximately 1 nm thick. Though thicker barrier layers 330 may also be used in some embodiments. In a particular embodiment, the thickness of the barrier layer 330 may be between approximately 10 Angstroms and approximately 500 Angstroms.

In an embodiment, the barrier layer 330 may be selectively formed over conductive features. For example, the barrier layer 330 may be provided over at least three sides of the traces 315 and at least three sides of the pad 310. In the case of the pad 310, the barrier layer 330 may be provided over sidewalls 312 and over a top surface 311 of the pad 310. The barrier layer 330 is also formed with a selective process, so that the top surface 303 of the first package substrate layer 301 is not covered by the barrier layer 330. This may aid in improving adhesion between layers in some embodiments. In an embodiment, the barrier layer 330 may be selectively deposited with an autocatalytic plating (or electroless plating) process. That is, since there is no seed layer provided over the top surface 303 of the first package substrate layer 301, the metal will not plate, whereas the metal of the traces 315 and the pad 310 provide the metal for initiating the plating of the barrier layer 330.

Referring now to FIG. 3C, a cross-sectional illustration of the electronic package after a second package substrate layer 302 is provided over the first package substrate layer 301 is shown, in accordance with an embodiment. In an embodiment, the second package substrate layer 302 may be substantially similar to the first package substrate layer 301. For example, the second package substrate layer 302 may be an organic buildup film or the like. The second package substrate 302 may be directly bonded to the first package substrate layer 301 without any intervening layer. This may improve adhesion of the second package substrate layer 302 to the first package substrate layer 301. In an embodiment, the second package substrate layer 302 may be applied with a lamination process of the like. A thickness of the second package substrate layer 302 may be up to approximately 50 μm in some embodiments. For example, the second package substrate layer 302 may have a thickness that is between approximately 10 μm and approximately 30 μm in some embodiments.

Referring now to FIG. 3D, a cross-sectional illustration of the electronic package after a via opening 325 is formed in the second package substrate layer 302 is shown, in accordance with an embodiment. In an embodiment, the via opening 325 may be provided over the pad 310. The via opening 325 may result in the removal of portions of the second package substrate layer 302. The via opening 325 may expose a portion of the barrier layer 330 over the pad 310. In an embodiment, the via opening 325 may be formed with any suitable material removal process. In the case shown in FIG. 3D, the via opening 325 is formed with a laser ablation process. Laser ablation processes may result in a via opening 325 that has tapered sidewalls. That is, a top of the via opening 325 may be wider than a bottom of the via opening 325. Though, it is to be appreciated that other patterning processes may also be used to form the via opening 325, such as lithography or the like. In the case of a lithography defined via opening 325, the sidewalls of the via opening 325 may be substantially vertical.

Referring now to FIG. 3E, a cross-sectional illustration of the electronic package after a via 327 and overlying pad 328 are formed is shown, in accordance with an embodiment. In an embodiment, the overlying pad 328 and the via 327 may comprise copper or any other suitable electrically conductive material or materials. The via 327 may land directly on, and make direct contact with, the barrier layer 330. That is, since the barrier layer 330 is electrically conductive, the barrier layer 330 does not need to be removed from the pad 310. This results in the omission of at least one processing operation compared to embodiments described in greater detail above. Accordingly, electrical coupling between the overlying pad 328 and the pad 310 may be provided by a combination of the barrier layer 330 and the via 327.

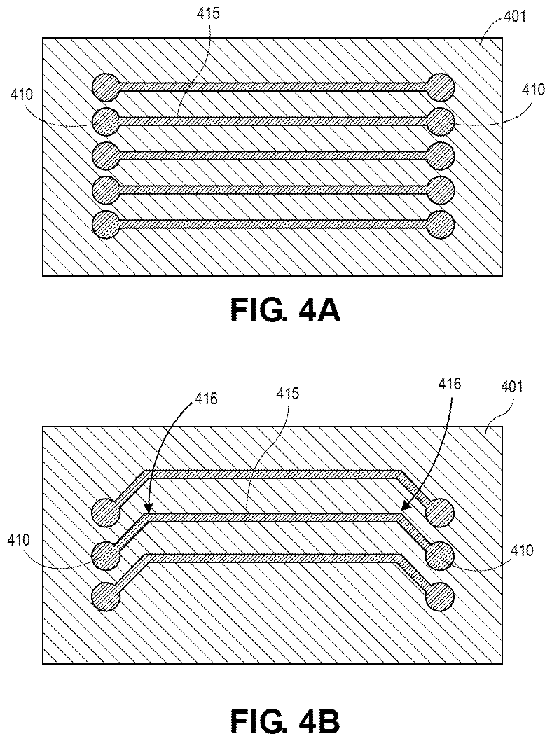

As noted above, the improved electromigration performance of traces in accordance with embodiments described herein may allow for the reduction in design rules. As such, smaller L/S dimensions may be enabled without the need for a restrictive set of design rules. For example, in previous implementations of HDP applications, straight lines were problematic, particularly for long trace lengths. However, embodiments disclosed herein enable long and straight routing topologies. Additionally, traces with one or more bends may also be used in accordance with embodiments disclosed herein. Examples of such embodiments are illustrated in FIGS. 4A and 4B.

Referring now to FIG. 4A, a portion of an electronic package is shown, in accordance with an embodiment. In an embodiment, the electronic package comprises a package substrate layer 401. The package substrate layer 401 may be provided over other package substrate layers, over a core, or over any other suitable structure. In an embodiment, the pads 410 may be provided on the package substrate layer 401. The pads 410 may be electrically coupled together by traces 415. In an embodiment, the traces 415 may have substantially straight paths (i.e., without any bends or turns). In an embodiment, a length of the traces 415 may be up to approximately 600 μm or longer. The traces 415 may also have L/S dimensions of approximately 5 μm/5 μm or less in some embodiments.

In an embodiment, the traces 415 and the pads 410 may comprise a barrier layer (not shown). The barrier layer may be similar to any of the barrier layers described in greater detail above. In one embodiment, the barrier layer may comprise an electrically conductive barrier layer. For example, the barrier layer comprise one or more of cobalt, tungsten, and phosphates. The barrier layer may have a thickness that is up to approximately 1 nm in some instances. For example, the barrier layer may have a thickness that is between approximately 10 Angstroms and approximately 500 Angstroms.

In an embodiment, the barrier layer is selectively formed over conductive features. As such, the barrier layer may be absent from the top surface of the package substrate layer 401. That is, the barrier layer may be provided only over sidewalls and top surfaces of the traces 415 and the pads 410. Since the barrier layer is conductive, overlying vias (not shown) do not need to pass through the barrier layer. Instead, the overlying vias may land directly on the barrier layer over the pads 410.

Referring now to FIG. 4B, a plan view illustration of an electronic package is shown, in accordance with an additional embodiment. In an embodiment, the electronic package in FIG. 4B may be substantially similar to the electronic package in FIG. 4A, with the exception of the routing path of the plurality of traces 415. Instead of being straight line paths, the traces 415 may include one or more bends 416 or turns. In the illustrated embodiment, the bends 416 are shown as being 45 degree turns. Though, turns with other angles may also be used in some embodiments. Further, while a bend 416 is shown at both the left end and the right end of the traces 415, it is to be appreciated that one bend 416 or more than two bends 416 may be included in each of the traces 415. Further, while embodiments show either straight traces 415 (i.e., FIG. 4A) and bent traces 415 (i.e., FIG. 4B), embodiments may include both bent and straight traces 415 within a single package substrate layer 401.

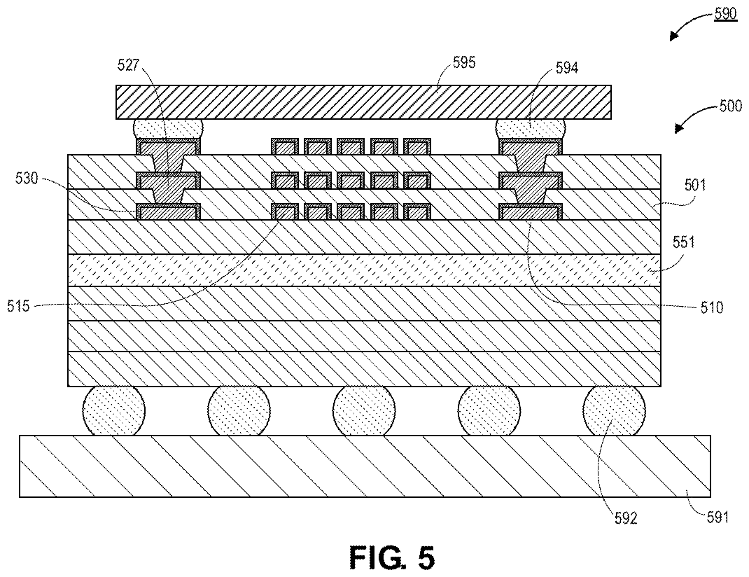

Referring now to FIG. 5, a cross-sectional illustration of an electronic system 590 is shown, in accordance with an embodiment. In an embodiment, the electronic system 590 may comprise a board 591, such as a printed circuit board (PCB). The board 591 may be electrically coupled to an electronic package 500 by interconnects 592, such as solder balls, sockets, or the like.

In an embodiment, the electronic package 500 may comprise a core 551. The core 551 may be a glass core, an organic core, or any other type of core material. While shown with a core 551, it is to be appreciated that coreless architectures may also be used in some embodiments. In an embodiment, package substrate layers 501 may be provided over and under the core 551 in some embodiment. The package substrate layers 501 may be organic buildup film layers or the like.

In an embodiment, conductive routing may be provided on and/or in the package substrate layers 501. For example, the conductive routing may include traces 515 and pads 510. The pads 510 may be coupled to each other between layers by vias 527. In an embodiment, the conductive routing may include high density routing with fine L/S dimensions (e.g., up to approximately 5 μm/5 μm). The conductive routing may be lined by an electrically conductive barrier layer 530, such as any of the electrically conductive barrier layers described in greater detail above. Since the barrier layer 530 is electrically conductive, the vias 527 may land directly on the barrier layer 530 instead of needing to pass through the barrier layer 530. Further, the barrier layer 530 is selectively formed only over conductive features using an autocatalytic process, so the conductive features are not shorted together by a seed layer or the like.

In an embodiment, one or more dies 595 may be electrically coupled to the electronic package 500 by interconnects 594. The interconnects 594 may be solder balls, copper bumps, or any other first level interconnect (FLI) architecture. In an embodiment, the one or more dies 595 may comprise compute dies such as, a central processing unit (CPU), a graphics processing unit (GPU), an XPU, a system on a chip (SoC), a communications die, a memory, or the like.

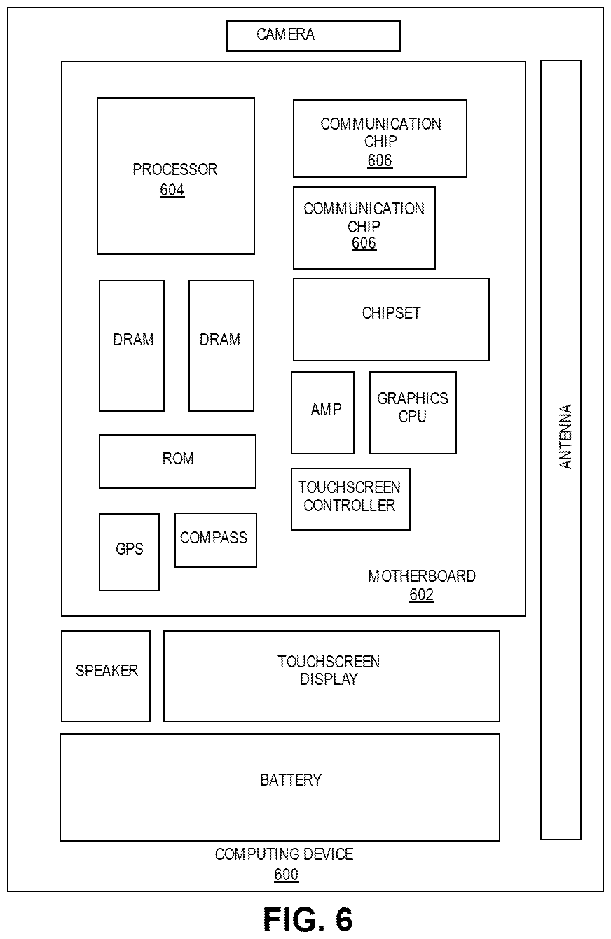

FIG. 6 illustrates a computing device 600 in accordance with one implementation of the invention. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the invention, the integrated circuit die of the processor may be part of an electronic package that comprises an electronic package with fine L/S dimensions where the conductive routing is covered by an electrically conductive barrier layer, in accordance with embodiments described herein. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the invention, the integrated circuit die of the communication chip may be part of an electronic package that comprises an electronic package with fine L/S dimensions where the conductive routing is covered by an electrically conductive barrier layer, in accordance with embodiments described herein.

In an embodiment, the computing device 600 may be part of any apparatus. For example, the computing device may be part of a personal computer, a server, a mobile device, a tablet, an automobile, or the like. That is, the computing device 600 is not limited to being used for any particular type of system, and the computing device 600 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a package substrate, comprising: a substrate layer; a plurality of traces on the substrate layer, wherein each of the plurality of traces are covered on sidewalls and an entire top surface by a first layer; and a pad on the substrate layer, wherein the pad is covered on sidewalls and an entire top surface by a second layer.

Example 2: the package substrate of Example 1, wherein the first layer is the same as the second layer.

Example 3: the package substrate of Example 1 or Example 2, wherein the first layer and/or the second layer comprise cobalt.

Example 4: the package substrate of Example 3, wherein the first layer and/or the second layer further comprise tungsten and a phosphate.

Example 5: the package substrate of Examples 1-4, wherein the first layer and the second layer have a thickness that is less than approximately 1 nm.

Example 6: the package substrate of Example 5, wherein the thickness is between approximately 10 Angstroms and approximately 500 Angstroms.

Example 7: the package substrate of Examples 1-6, wherein the first layer and the second layer do not cover the top surface of the substrate layer.

Example 8: package substrate of Examples 1-7, further comprising: a second substrate layer over the substrate layer; and a via through the second substrate layer, wherein the via lands on, and is in direct contact with, the second layer.

Example 9: the package substrate of Examples 1-8, wherein the plurality of traces have a line/spacing dimension of approximately 5 μm/5 μm or less.

Example 10: the package substrate of Examples 1-9, wherein each of the plurality of traces have one or more bends or turns.

Example 11: a device, comprising: a first substrate layer; a pad on the first substrate layer, wherein the pad has sidewall surfaces and a top surface; a barrier layer on the pad, wherein the barrier layer entirely covers the sidewall surfaces and the top surface of the pad; a second substrate layer over the first substrate layer; and a via that passes through the second substrate layer, wherein the via is in direct contact with the barrier layer over the top surface of the pad.

Example 12: the device of Example 11, wherein the barrier layer is electrically conductive.

Example 13: the device of Example 12, wherein the barrier layer comprises cobalt.

Example 14: the device of Example 13, wherein the barrier layer further comprises tungsten and a phosphate.

Example 15: the device of Examples 11-14, wherein the barrier layer has a thickness that is approximately 1 nm or less.

Example 16: the device of Examples 11-15, wherein the first substrate layer and the second substrate layer are part of a package substrate.

Example 17: the device of Examples 11-16, wherein the first substrate layer and the second substrate layer are part of a semiconductor die.

Example 18: an electronic system, comprising: a board; a package substrate coupled to the board; and a die coupled to the package substrate, wherein one or both of the package substrate and the die comprise traces that are lined along sidewalls and top surfaces by a barrier layer that comprises cobalt.

Example 19: the electronic system of Example 18, wherein the barrier layer has a thickness that is approximately 1 nm or less.

Example 20: the electronic system of Example 18 or Example 19, wherein the electronic system is part of a personal computer, a server, a mobile device, a tablet, or an automobile.

What is claimed is:

1. A package substrate, comprising:
a substrate layer;
a plurality of traces on the substrate layer, wherein each of the plurality of traces are covered on sidewalls and an entire top surface by a first layer; and
a pad on the substrate layer, wherein the pad is covered on sidewalls and an entire top surface by a second layer.

2. The package substrate of claim 1, wherein the first layer is the same as the second layer.

3. The package substrate of claim 1, wherein the first layer and/or the second layer comprise cobalt.

4. The package substrate of claim 3, wherein the first layer and/or the second layer further comprise tungsten and a phosphate.

5. The package substrate of claim 1, wherein the first layer and the second layer have a thickness that is less than approximately 1 nm.

6. The package substrate of claim 5, wherein the thickness is between approximately 10 Angstroms and approximately 500 Angstroms.

7. The package substrate of claim 1, wherein the first layer and the second layer do not cover the top surface of the substrate layer.

8. The package substrate of claim 1, further comprising:
a second substrate layer over the substrate layer; and
a via through the second substrate layer, wherein the via lands on, and is in direct contact with, the second layer.

9. The package substrate of claim 1, wherein the plurality of traces have a line/spacing dimension of approximately 5 μm/5 μm or less.

10. The package substrate of claim 1, wherein each of the plurality of traces have one or more bends or turns.

11. A device, comprising:
a first substrate layer;
a pad on the first substrate layer, wherein the pad has sidewall surfaces and a top surface;
a barrier layer on the pad, wherein the barrier layer entirely covers the sidewall surfaces and the top surface of the pad;
a second substrate layer over the first substrate layer; and
a via that passes through the second substrate layer, wherein the via is in direct contact with the barrier layer over the top surface of the pad.

12. The device of claim 11, wherein the barrier layer is electrically conductive.

13. The device of claim 12, wherein the barrier layer comprises cobalt.

14. The device of claim 13, wherein the barrier layer further comprises tungsten and a phosphate.

15. The device of claim 11, wherein the barrier layer has a thickness that is approximately 1 nm or less.

16. The device of claim 11, wherein the first substrate layer and the second substrate layer are part of a package substrate.

17. The device of claim 11, wherein the first substrate layer and the second substrate layer are part of a semiconductor die.

18. An electronic system, comprising:
a board;
a package substrate coupled to the board; and
a die coupled to the package substrate, wherein one or both of the package substrate and the die comprise traces that are lined along sidewalls and top surfaces by a barrier layer that comprises cobalt.

19. The electronic system of claim 18, wherein the barrier layer has a thickness that is approximately 1 nm or less.

20. The electronic system of claim 18, wherein the electronic system is part of a personal computer, a server, a mobile device, a tablet, or an automobile.
